(19) United States
(12) Patent Application Publication
(10) Pub. No.: US 2026/0342071 A1
(43) Pub. Date: Oct. 29, 2026

(54) NEW ENERGY PHOTOVOLTAIC MULTI-BRANCH VERTICAL OUTGOING CONFLUENCE METHOD

(71) Applicant: SUNKEAN CABLE CO., LTD., Wuxi (CN)

(72) Inventors: Dongsheng Wang, Wuxi (CN); Mingming Xu, Yancheng (CN); Zhumiao Guo, Zhenjiang (CN); Qi Tang, Wuxi (CN); Jun Dai, Fuzhou (CN)

(21) Appl. No.: 19/718,964

(22) Filed: Jun. 24, 2026

(51) Int. Cl. H02G 15/18; H01B 1/02; H01R 4/02

(52) U.S. Cl. CPC H02G 15/18; H01B 1/023; H01B 1/026; H01R 4/021

(57) ABSTRACT

Provided is a new energy photovoltaic multi-branch vertical outgoing confluence method, which includes taking any one photovoltaic confluence branch as a main path and other photovoltaic confluence branches as branch paths, arranging each of the branch paths vertically with the main path and electrically connecting them; allocating current of each of the branch paths in an equal or predetermined ratio manner; and unified outputting photovoltaic energy through the main path. Through vertical outgoing and converging structure, the routing of each branch path is staggered, rendering it difficult for the cables to bend during the packaging process, thereby effectively eliminating residual stress and avoiding laying stress during on-site installation, thus reducing installation difficulty.

### TECHNICAL FIELD

The present application relates to the field of photovoltaic energy output technologies, and in particular, to a new energy photovoltaic multi-branch vertical outgoing confluence method.

### BACKGROUND

Photovoltaic power generation, as the core utilization form of renewable clean energy, relies on the photovoltaic effect to directly convert solar energy into electrical energy. It has the advantages of zero carbon emissions, stable operation, flexible deployment, and long-life cycle. It is the core supporting technology for the implementation of China's dual carbon strategy and the construction of a new power system. After using photovoltaic devices for power generation, the electrical energy generated by each photovoltaic device needs to be flowed together into the power grid for unified power transmission. At present, the traditional method of parallel outgoing lines is widely used in industry to converge the electrical energy of various photovoltaic devices. Specifically, each photovoltaic device corresponds to a photovoltaic cable confluence branch, and all photovoltaic cable confluence branches are arranged in parallel, that is, each photovoltaic confluence branch is arranged in the same direction, parallel to each other, and jointly connected to the confluence box or distribution device. Then, the line from the confluence box or distribution device is connected to the power grid cable, and transmitted to the external network through the power grid cable. However, this parallel outgoing line structure, with each branch running in the same direction and arranged in parallel, makes the cables prone to bending deformation due to compression during the packaging stage of the finished product, resulting in residual internal stress. This further transforms into laying stress during on-site laying operations, which not only increases the difficulty of construction, but also easily causes cable damage and abnormal stress at connection positions.

### SUMMARY

The present application provides a new energy photovoltaic multi-branch vertical outgoing confluence method. Through the vertically outgoing confluence structure, the routing of each branch path is staggered, and the cables are not easily bent during the packaging process, thereby effectively eliminating residual stress and avoiding laying stress during on-site installation and thus reducing installation difficulty.

The present application provides a new energy photovoltaic multi-branch vertical outgoing confluence method, including:
step S101: taking any one photovoltaic confluence branch as a main path and other photovoltaic confluence branches as branch paths, arranging each of the branch paths vertically with the main path and electrically connecting them;
step 102: allocating current of each of the branch paths in an equal or predetermined ratio manner;
step 103: unified outputting photovoltaic energy through the main path.

In some embodiments of the present disclosure, arranging each of the branch paths vertically with the main path and electrically connecting them include:
connecting each of the branch paths to the main path through a cross-shaped or T-shaped connection method, where connection ways between different branch paths and the main path are the same or different.

In some embodiments of the present disclosure, in step 102, allocating current of each of the branch paths in an equal or predetermined ratio manner includes:
pre-setting a current distribution ratio based on the number of the branch paths, line diameters of the branch paths, or power demands of the branch paths;
allocating the current of each of the branch paths according to a pre-set current distribution ratio.

In some embodiments of the present disclosure, arranging each of the branch paths vertically with the main path and electrically connecting them include:
when the branch paths are aluminum cables, connecting the branch paths of the aluminum cables to the main path through a copper aluminum transition structure, or directly connecting the branch paths of the aluminum cables to the main path;
when the branch paths are copper cables, connecting the branch paths of the copper cables directly to the main path.

In some embodiments of the present disclosure, arranging each of the branch paths vertically with the main path and electrically connecting them includes:
distributing connection positions between each of the branch paths and the main path at a predetermined distance interval.

In some embodiments of the present disclosure, after arranging each of the branch paths vertically with the main path and electrically connecting them, the method further includes:
providing protection structures at the connection positions between each of the branch paths and the main path, wrapping the connection positions between the branch paths and the main path by the protection structures, and connecting the protection structures with the connection positions between the branch paths and main path through an adhesive layer.

In some embodiments of the present disclosure, arranging each of the branch paths vertically with the main path and electrically connecting them include:
connecting the branch paths and main path electrically by welding, or;
connecting the branch paths to the main path through conductive connectors, where the branch paths are welded to the conductive connectors, and the conductive connectors are welded to the main path.

In some embodiments of the present disclosure, the protection structures of the present application include an inner protective layer and an outer protective layer, where the inner protective layer is sleeved on an outer circumference of a cable connection position, the outer protective layer is fixedly provided on an outer circumference of the inner protective layer, and an adhesive layer is provided between the protection structures and a cable.

In some embodiments of the present disclosure, the outer protective layer includes multiple protection sections, each of the multiple protection sections is fixedly connected to form the outer protective layer.

In some embodiments of the present disclosure, reinforcing ribs are fixedly provided between each of the multiple protection sections.

In some embodiments of the present disclosure, each of the multiple protection sections is provided with a necking section.

In some embodiments of the present disclosure, the protection sections are prismatic-shaped, and the necking sections are cylindrical-shaped.

In some embodiments of the present disclosure, the protection sections are provided with rounded corners.

In some embodiments of the present disclosure, the necking sections is fixedly provided with at least one necking convex ring.

In some embodiments of the present disclosure, the protection structures also include a conductive connector, and the conductive connector is provided inside the inner protective layer and contacts the cable connection position, where the conductive connector has conductive properties.

In some embodiments of the present disclosure, the inner and outer protective layers can be made of flexible or hard materials.

A confluence method for new energy photovoltaic multi-branch, including:
S1: pre-welding and forming a main cable and a branch cable, separately;
S2: arranging the main cable and the branch cable in a cross-shaped or T-shaped staggered manner and placing them on a bottom mold of a welding device, and causing a top mold of the welding device to press on the main cable and branch cable;
S3: fixing the main cable and branch cable through welding, by the welding device;
S4: using protection structures to wrap and protect cable connections where the main cable and branch cable are welded together.

In summary, the present application includes at least one beneficial technical effect as follows:
the present application divides the photovoltaic confluence branches into the main path and branch paths, so that all branch paths are arranged vertically with the main path and they are electrically connected, which abandons the traditional parallel outgoing line mode. This layout allows the routing of each branch path to be staggered, and the cables are not easily bent during the packaging process, thereby effectively eliminating residual stress; when laying on site, there is no laying stress caused by parallel arrangement of lines, thereby greatly reducing installation difficulty. At the same time, by evenly or pre-proportionally distributing the current of each branch path, the load of the lines is balanced, further improving the installation convenience and operational reliability of the confluence system.

### BRIEF DESCRIPTION OF DRAWINGS

FIG. 1A is a flowchart of a new energy photovoltaic multi-branch vertical outgoing confluence method according to an embodiment of the present application.

FIG. 1B is a first overall structure schematic diagram in an embodiment of the present application.

FIG. 2 is a first exploded view diagram of the overall structure in an embodiment of the present application.

FIG. 3 is a second exploded view diagram of the overall structure in an embodiment of the present application.

FIG. 4 is a vertical view diagram of the overall structure in an embodiment of the present application.

FIG. 5 is a first cable confluence method in an embodiment of the present application.

FIG. 6 is a second cable confluence method in an embodiment of the present application.

FIG. 7 is a third cable confluence method in an embodiment of the present application.

FIG. 8 is a fourth cable confluence method in an embodiment of the present application.

FIG. 9 is a fifth cable confluence method in an embodiment of the present application.

FIG. 10 is a sixth cable confluence method in an embodiment of the present application.

FIG. 11 is a schematic diagram of a multi-branch vertical outgoing confluence method in an embodiment of the present application.

FIG. 12 is a logical schematic diagram in an embodiment of the present application.

Numeral reference: 1—inner protective layer, 2—outer protective layer, 21—protection section, 211, rounded corner, 22—reinforcing rib, 23—necking section, 231—necking convex ring, 3—conductive connector, 10—main path, 101—cable connection position, 20—protection structure, 30—branch path.

### DESCRIPTION OF EMBODIMENTS

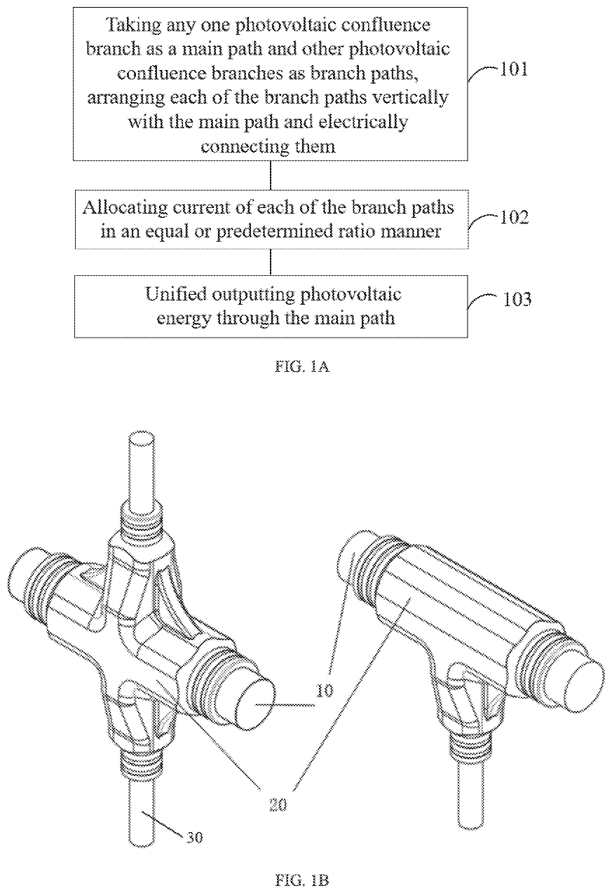

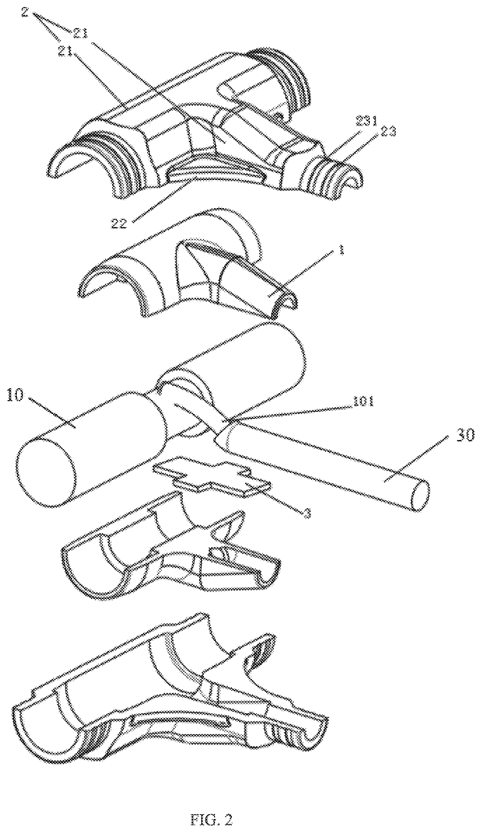

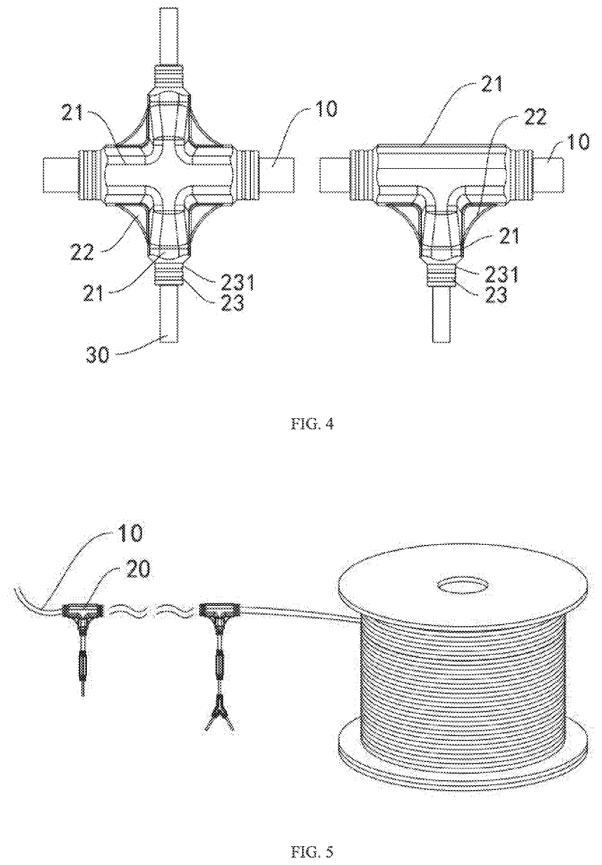

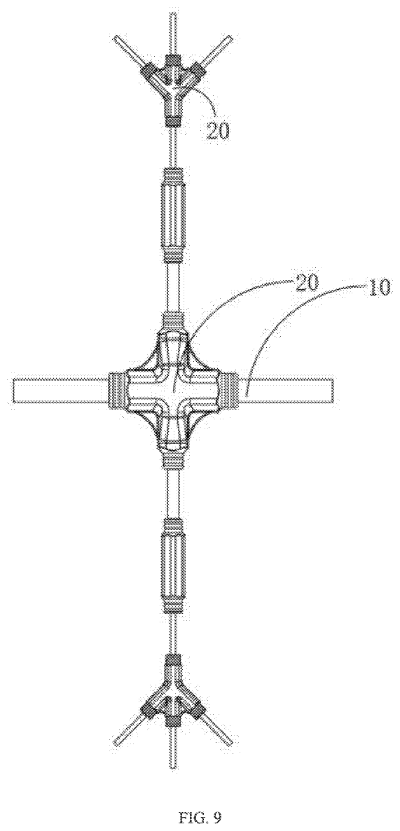

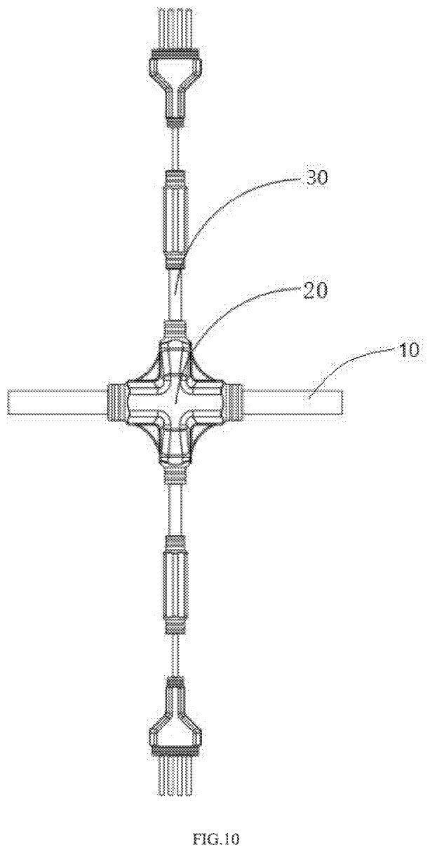

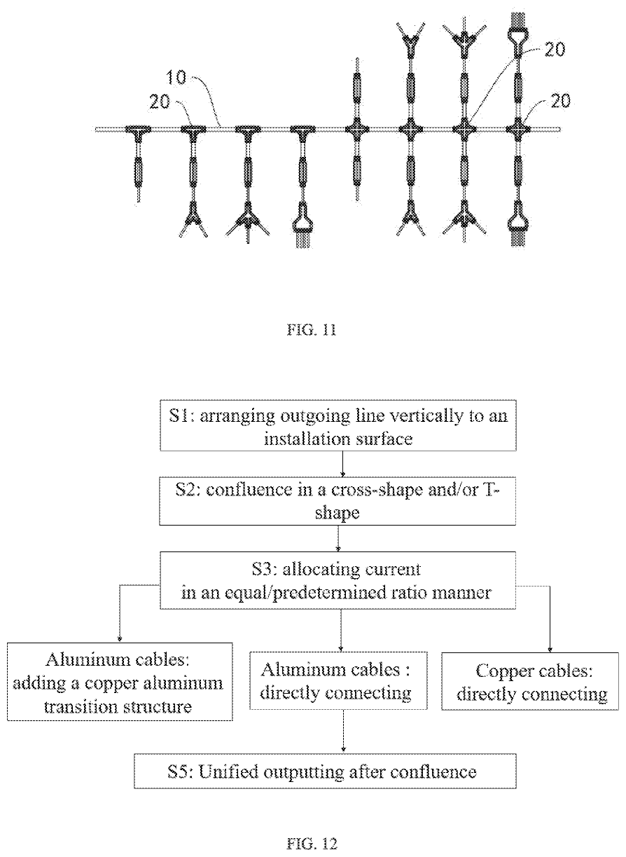

Further detailed explanations of the present application will be provided in combination with FIGS. 1-13.

Referring to FIG. 1A, the present application provides a new energy photovoltaic multi-branch vertical outgoing confluence method, including:
step S101: taking any one photovoltaic confluence branch as a main path 10 and other photovoltaic confluence branches as branch paths 30, arranging each of the branch paths 30 vertically with the main path 10 and electrically connecting them;
step 102: allocating current of each of the branch paths 30 in an equal or predetermined ratio manner;
step 103: unified outputting photovoltaic energy through the main path 10;
where each of the branch paths 30 is electrically connected to the main path 10 through vertical wiring, and each of the branch paths 30 converges to the main path 10; the main path 10 uniformly outputs photovoltaic energy to a confluence box or a distribution device, and then outputs it to a power grid cable through the confluence box or distribution device; through the above method, the routing of each of the branch paths 30 can be staggered, and the cables are not easily bent during the packaging process, effectively eliminating residual stress; when laying on site, there is no laying stress caused by parallel arrangement of lines, greatly reducing installation difficulty; at the same time, by evenly or pre proportionally distributing the current of each of the branch paths 30, the load of the lines is balanced, further improving the installation convenience and operational reliability of the confluence system.

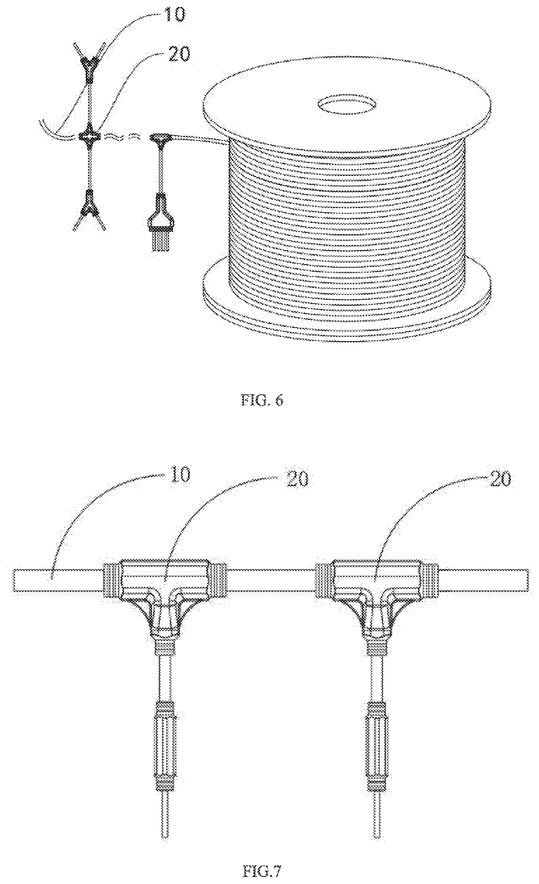

In an implementation mode, arranging each of the branch paths 30 vertically with the main path 10 and electrically connecting them include: connecting each of the branch paths 30 to the main path 10 through a cross-shaped or T-shaped connection method, where connection ways between different branch paths 30 and the main path 10 are the same or different. Referring to FIGS. 5 and 6, in FIG. 5, the main path 10 is connected to the branch paths 30 through a T-shaped connection, while in FIG. 6, the main path 10 is connected to one branch path 30 through a T-shaped connection and to another branch path 30 through a cross-shaped connection.

Where in step S2, allocating current of each of the branch paths 30 in an equal or predetermined ratio manner includes: pre-setting a current distribution ratio based on the number of the branch paths 30, line diameters of the branch paths 30, or power demands of the branch paths 30; allocating the current of each of the branch paths 30 according to a pre-set current distribution ratio.

In an implementation mode, arranging each of the branch paths 30 vertically with the main path 10 and electrically connecting them include: when the branch paths 30 are aluminum cables, connecting the branch paths 30 of the aluminum cables to the main path 10 through a copper aluminum transition structure, or directly connecting the branch paths 30 of the aluminum cables to the main path 10; when the branch paths 30 are copper cables, connecting the branch paths 30 of the copper cables directly to the main path 10. The copper aluminum transition structure refers to connecting the aluminum cable to the copper cable first, and then connecting the copper cable to the main path 10, thereby achieving the conversion of the aluminum cable to the copper cable and then converging.

In an implementation mode, arranging each of the branch paths 30 vertically with the main path 10 and electrically connecting them include: distributing connection positions 101 between each of the branch paths 30 and the main path 10 at a predetermined distance interval. The confluence nodes of each of the branch paths 30 and the main path 10 are arranged in a dispersed manner, which can disperse heat and avoid local overheating of the confluence nodes.

In an implementation mode, after arranging each of the branch paths 30 vertically with the main path 10 and electrically connecting them, the method further includes: providing protection structures 20 at the connection positions between each of the branch paths 30 and main path 10, the protection structures 20 wrap around the connection positions between the branch paths 30 and main path 10, and connecting the protection structures 20 with the connection positions between the branch paths 30 and main path 10 through an adhesive layer.

In an implementation mode, arranging each of the branch paths 30 vertically with the main path 10 and electrically connecting them include: electrically connecting the branch paths 30 and main path 10 through welding; alternatively, electrically connecting the branch paths 30 to the main path 10 through conductive connectors 3, where the branch paths 30 are welded to the conductive connectors 3, and the conductive connectors 3 are welded to the main path 10.

In an implementation mode, the branch paths 30 of the present application can be arranged separately using a T-shaped connection method, with the outgoing line perpendicular to the main path 10, thereby forming T-shaped confluence nodes between the branch paths 30 and the main path 10. Rear ends of the branch paths 30 away from the T-shaped confluence nodes can also be connected to four-path copper cable path, and the four-path copper cable path can be directly connected to the T-shaped confluence nodes. The four path currents are evenly distributed, and on the main path, one total current is divided into four sub currents, without copper aluminum conversion process.

In an implementation mode, the present application can also first gather three branch paths in a cross-shape and then connect in series in a T-shaped structure at the back end. Two of the branch paths are aluminum cable branch paths, and copper aluminum transition structures are provided between the aluminum cable and the confluence nodes, respectively. The remaining two copper cables are directly connected; allocating current of each path according to a preset ratio of 3:2 to achieve one total current is divided into five sub currents in the main path.

Alternatively, a cross-shaped connection can be used separately for layout, with five mixed copper aluminum branch paths and copper aluminum transition structures added to the aluminum cables. Multiple gear ratios can be set according to the photovoltaic power of each branch path, and branch path currents can be distributed differentially to meet the selection of multiple gear power consumption.

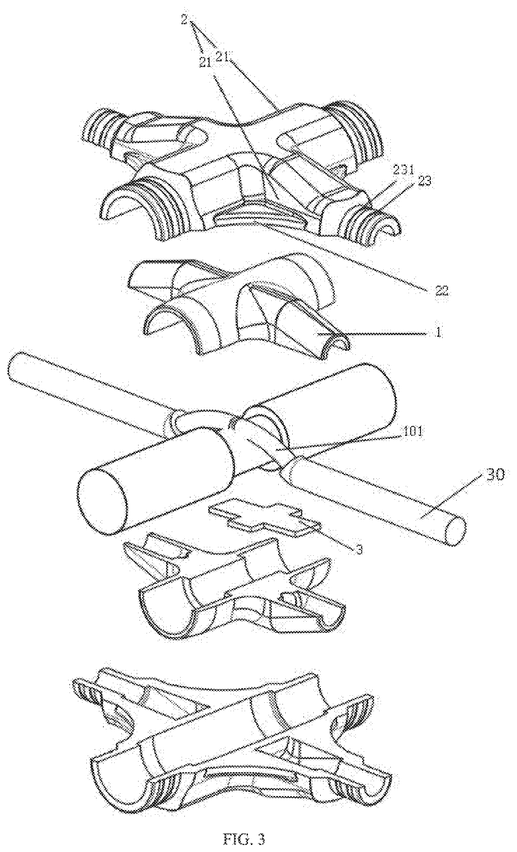

Referring to FIG. 2, the electrical connection position between the branch paths 30 and main path 10 is a cable connection position 101. In the present application, the protection structures 20 include an inner protective layer 1 and an outer protective layer 2. The inner protective layer 1 is sleeved around an outer circumference of the cable connection position 101, and the outer protective layer 2 is fixedly provided around an outer circumference of the inner protective layer 1. There is an adhesive layer between the protective layer and a cable.

It should be understood that the inner protective layer 1 refers to a protective layer directly wrapped around the outer circumference of the cable connection position 101, adhered to a surface of the cable connection position 101, thereby providing basic insulation and sealing protection. The protective layer is connected to the cable connection position 101 through the adhesive layer, and the adhesive layer is an adhesive coated on the outer surface of the cable to ensure stable fixation on the cable connection position 101 and prevent relative displacement or detachment caused by cable shaking. The outer protective layer 2 refers to a protective layer provided on the outer circumference of the inner protective layer 1, and the outer protective layer 2 is fixedly provided on the outer circumference of the inner protective layer 1. The two can be connected by interference fit, adhesion or other fixing methods. The outer protective layer 2 protects the internal cable connection position 101 when subjected by external compression or impact. The adhesive layer refers to a dielectric layer with adhesive properties. In an implementation mode of the present application, the adhesive layer is provided between the inner protective layer 1 and the cable connection position 101, that is, the inner protective layer 1 is connected to the branch paths 30 and the main path 10 through the adhesive layer, to achieve direct and firm adhesion between the inner protective layer 1 and the cable; in an implementation mode of the present application, the adhesive layer can also be placed between the inner protective layer 1 and the outer protective layer 2 to enhance the bonding force between the two layers and prevent delamination. It can be understood that regardless of whether the adhesive layer is placed between the inner protective layer 1 and the cable connection position 101/the outer protective layer 2, the adhesive layer can fix the inner protective layer 1, thereby shaping the shape of the inner protective layer 1 provided at the cable connection position 101 and preventing shrinkage and other problems of the inner protective layer 1. The specific composition of the adhesive layer can be selected according to the present application scenario, such as hot melt adhesive, pressure-sensitive adhesive or epoxy resin adhesive, etc. This embodiment of the present application does not make special limitations on this.

In an implementation mode of the present application, the outer protective layer 2 includes multiple protection sections 21, and the multiple protection sections 21 are fixedly connected to each other to form the outer protective layer 2. The protection sections 21 refer to the basic structural units that make up the outer protective layer 2. The number and arrangement of the protection sections 21 depend on the shape of the cable connection position 101, for example, the cable connection position 101 is a two-cable confluence type cable connection position 101, the number of the protection sections 21 is three, the cable connection position 101 is a three-cable confluence type cable connection position 101, and there are four protection sections 21. The specific quantity is not specifically limited in the present application.

In an implementation mode, reinforcing ribs 22 are fixedly provided between each of the protection sections 21. The reinforcing ribs 22 refer to structural connecting components provided between adjacent protection sections 21. The reinforcing ribs 22 are used to provide additional mechanical support and connection strength for the outer protective layer 2. The fixed connection method between the reinforcing ribs 22 and each of the protection sections 21 is an integrated fixed connection method, so that when the outer protective layer 2 is subjected to external impact, compression or long-term vibration, the reinforcing ribs 22 can bear some stress, limit relative displacement, misalignment or cracking between adjacent protection sections 21, and maintain the structural integrity of the outer protective layer 2.

In an implementation mode, each of the protection sections 21 is provided with a necking section 23, and the necking section 23 refers to a structural component provided at one end of the protection section 21 and configured to achieve a transition connection with a cable body. The necking section 23 is configured to seal one end of the outer protective layer 2 to eliminate any gaps that may exist between the end of the protection section 21 and the connection positions of the main path 10. Besides that, it is also used to form a transition interface from the outer protective layer 2 to the main path 10 body to block a path of external moisture, dust, and other impurities entering an interior through the end gap, so that the entire protection structures 20 forms a continuous sealed state in an end area.

In an implementation mode, a structural shape of the protection section 21 is prismatic, a structural shape of the necking section 23 is cylindrical, and a structural shape of the protection section 21 is prismatic, which refers to a cross-sectional or an overall shape of the protection section 21 presenting a polygonal cylindrical structure with multiple planes. The prismatic structure can be a regular hexagonal prism, a regular octagonal prism, or other polygonal prism structure. This embodiment of the present application does not make special limitations on this. As the main load-bearing part of the outer protective layer 2, the prismatic geometric shape of the protection section 21 can provide higher bending stiffness and torsional strength than traditional cylindrical structures. In an implementation mode, the protection section 21 is provided with rounded corners 211, and the rounded corners 211 refer to the rounded corners 211 of the protection section 21, a smooth transition surface formed by rounding edges or corners, thereby eliminating sharp edges by providing the rounded corners 211, to achieve a smooth transition of an surface contour, the outer protective layer 2 is subjected to more uniform force when subjected to lateral compression or friction, thereby avoiding the risk of cracking caused by angular stress concentration and improving operational safety. In an implementation mode, the necking section 23 is fixedly provided with a necking convex ring 231, and the necking convex ring 231 refers to an annular convex structure extending along a circumference of the necking section 23, and its cross-sectional shape can be semi-circular, trapezoidal, rectangular, etc. This embodiment of the present application is not particularly limited to this, and the necking convex ring 231 is fixedly provided on an outer surface of the necking section 23.

In this embodiment of the present application, the protection structures 20 further include a conductive connector 3, and the conductive connector 3 is provided inside the inner protective layer 1 and contacts the cable connection position 101. The conductive connector 3 has conductive properties, and the conductive connector 3 directly contacts the cable connection position 101, which means that a surface of the conductive connector 3 forms a physical contact with a metal conductor part of the cable, thereby establishing a current path between the two. The conductive connector 3 has conductive properties, and its material can be arranged according to the actual situation, for example, it can be a metal transition piece. This embodiment of the present application does not make special limitations on this. When the inner protective layer 1 wraps around the cable connection position 101, the conductive connector 3 is constrained between the inner protective layer 1 and the cable connection position 101. Due to a radial clamping force or an adhesive strength of the inner protective layer 1, the conductive connector 3 is tightly adhere to the surface of the cable connection position 101, thereby reducing the contact resistance and balancing the current distribution. Besides that, when the cable connection position 101 becomes slightly loose or the contact surface oxidizes due to long-term operation, the conductive connector 3 with conductive properties can act as a bypass conductive element to divert the current from a high resistance area to a low resistance area, avoiding the risk of insulation aging or melting caused by local overheating. The conductive connector 3 works in combination with the inner protective layer 1, and the inner protective layer 1 provides mechanical protection and environmental isolation, while the conductive connector 3 constructs a stable electrical connection environment internally, working together to ensure the long-term reliability of the photovoltaic junction node under complex working conditions

In an implementation mode of the present application, the inner protective layer 1 is made of flexible material, and the outer protective layer 2 is made of hard material. When the protection structures 20 are applied to the connection positions of photovoltaic cables, the inner protection structures 20 of the flexible material first wraps around the cable connection position 101, relying on its own elasticity to fully fill the connection gap, and can adapt to various bending postures of the cable, with strong adaptability; the outer protection structure made of hard and rigid material covers the outer side of the inner structure, thereby forming a stable and sturdy protective shell. When the external environment generates mechanical loads such as pressure and impact force, the hard outer protection structure can first bear most of the load and achieve stress dispersion, thereby effectively avoiding damage and puncture of the protective layer caused by excessive local pressure; when the cable is affected by wind load, thermal expansion and contraction, causing vibration and displacement, the flexible inner protection structure can consume vibration energy by its own damping characteristics, thereby effectively avoiding problems such as loose cable connection position 101 and poor contact. This protective cooperation mechanism enables the overall protection structure 20 to have excellent sealing adaptability and reliable mechanical protection strength, thus ensuring the stability of the photovoltaic cable connection position in all aspects.

In an implementation mode, the flexible and hard protection structures of the protection structures can be made of various adaptive materials. The flexible material can be any equivalent material in Thermoplastic Vulcanizate, (TPV), Polypropylene, (PP), Reinforced Thermoplastic, (RTP), and the hard material can be any equivalent material in hard Polyvinyl chloride, (PVC), Acrylonitrile Butadiene Styrene, (ABS) plastic, polycarbonate, Polyamide, (PA) nylon, and can be flexibly selected according to the environmental and working conditions of the actual usage scenario to meet protection needs of different scenarios.

The implementation principle of the protection structures 20 in the present application is as follows: the protection structures 20 constructs a protective system and is matched with the adhesive layer to achieve overall multi-layer stable fixation. Relying on the synergistic effect of the internal and external protection structures and the adhesive layer, it achieves comprehensive and reliable protection for a connection of photovoltaic cables. Specifically, the flexible inner protection structure is directly sleeved around the outer circumference of the cable connection position 101, and with its own wrapping characteristics, it conforms to a contour of the cable connection position 101, thereby forming a first sealed protective barrier; the hard outer protection structure is arranged on the outer side of the inner protection structure, thereby providing stable mechanical support and external protective foundation for the overall protection structures. At the same time, the adhesive layer is provided between the protective layer and the cable in this structure, which achieves physical bonding and fixation between the protection structures 20 and the cable body through the adhesive layer, greatly improving the overall structural stability of the protection structures 20. This structural design has significant advantages. Even when the cable is affected by external forces, thermal expansion and contraction, and other factors that cause shaking or displacement, the adhesive layer can effectively constrain the protection structures 20, suppress the phenomenon of contraction, sliding, and loosening of the protective layer, completely avoid problems of loosening and falling off of the protection structures 20 caused by cable vibration, and continuously ensure a tight wrapping effect of the protection structures 20 on the cable connection position 101, and stably play a sealing and protective role. At the same time, the flexible protection structure can adapt to the bending posture of the cables, fill connection gaps, and dissipate vibration energy through its own damping; the hard and rigid protection structure can withstand and disperse external pressure and impact loads, combined with the fastening effect of the adhesive layer, rendering the protection structures 20 have excellent sealing adaptability, anti-vibration stability, and mechanical protection strength, comprehensively ensuring the long-term reliability of the cable connection position 101 of the photovoltaic cable.

In an implementation mode, the flexible and hard double-layer protection structure of the protection structures 20 can be made of various suitable materials. The flexible material can be any equivalent material in TPV, PP, RTP, and the hard material can be any equivalent material in hard PVC, ABS plastic, polycarbonate, PA nylon. It can be flexibly selected according to the actual environment and working conditions of the usage scenario to meet the protection needs of different scenarios.

Maintaining a good sealing environment to prevent the intrusion of external air and moisture effectively solves the problems of decreased sealing and unstable electrical connections caused by the easy loosening and detachment of existing heat shrink tubes due to vibration, and improves the operational reliability and safety of photovoltaic junction nodes under complex working conditions.

Referring to FIGS. 6-10, a new energy photovoltaic multi-branch confluence method, including:
S1: pre-welding and forming a main cable and a branch cable, separately;
S2: arranging the main cable and the branch cable in a cross-shaped or T-shaped staggered manner and placing them on a bottom mold of a welding device, and causing a top mold of the welding device to press on the main cable and branch cable;
S3: fixing the main cable and branch cable through welding, by the welding device;
S4: using protection structures to wrap and protect cable connections where the main cable and branch cable are welded together, and the protection structures are the same as the protection structures 20 in the above embodiment.

It can be understood that according to the preset process selection, corresponding welding device and welding methods are used to complete the solidification operation: if ultrasonic welding is selected, frictional heat energy is generated through high-frequency vibration of the device, causing the welding contact surface to melt and fuse and solidify under pressure; if other welding methods such as resistance welding and hot melt welding are used, the corresponding welding contact surface (the contact surface between the cable and the connection piece, and the direct contact surface between the cable main path and the branch path) should be fully melted and solidified through the corresponding process heat source and pressurization method. Reliable conductive connection between the main and branch line of the cable is achieved through an adapted welding process, ensuring a dense structure and stable connection at the welding point, and completing the formation of a connection of the cable body.

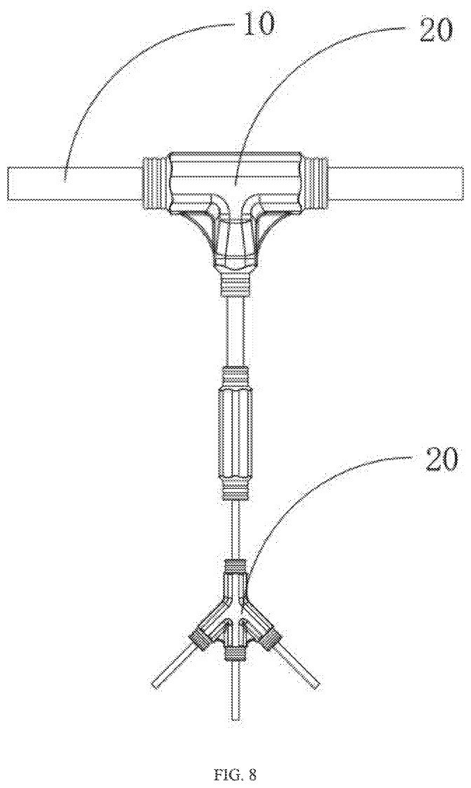

Refer to FIGS. 6-7 for vertical cable routing, packaging and on-site assembly do not require bending of cables, thereby eliminating laying stress and preventing cable bending and damage issues. This results in higher utilization of wiring space and flexible wiring layout; cross-shaped and T-shaped multi-point decentralized confluence, breaking the single point centralized confluence structure, dispersing heat sources, effectively suppressing local overheating at confluence points, and protecting the stable operation of circuits; supports two current distribution methods: equal distribution and custom ratio.

The above are the preferred embodiments of the present application and do not limit the protection scope of the present application. Therefore, any equivalent changes made according to the structure, shape, and principle of the present application should be included in the protection scope of the present application.

What is claimed is:

1. A new energy photovoltaic multi-branch vertical outgoing confluence method, comprising:
step S101: taking any one photovoltaic confluence branch as a main path and other photovoltaic confluence branches as branch paths, arranging each of the branch paths vertically with the main path and electrically connecting them;
step 102: allocating current of each of the branch paths in an equal or predetermined ratio manner;
step 103: unified outputting photovoltaic energy through the main path.

2. The method according to claim 1, wherein arranging each of the branch paths vertically with the main path and electrically connecting them comprise:
connecting each of the branch paths to the main path through a cross-shaped or T-shaped connection method, where connection ways between different branch paths and the main path are the same or different.

3. The method according to claim 1, wherein in step 102, allocating current of each of the branch paths in an equal or predetermined ratio manner, comprises:
pre-setting a current distribution ratio based on the number of the branch paths, line diameters of the branch paths, or power demands of the branch paths;
allocating the current of each of the branch paths according to a pre-set current distribution ratio.

4. The method according to claim 1, wherein arranging each of the branch paths vertically with the main path and electrically connecting them comprise:
wherein when the branch paths are aluminum cables, connecting the branch paths of the aluminum cables to the main path through a copper aluminum transition structure, or directly connecting the branch paths of the aluminum cables to the main path;
wherein when the branch paths are copper cables, connecting the branch paths of the copper cables directly to the main path.

5. The method according to claim 1, wherein arranging each of the branch paths vertically with the main path and electrically connecting them comprise:
distributing connection positions between each of the branch paths and the main path at a predetermined distance interval.

6. The method according to claim 1, wherein after arranging each of the branch paths vertically with the main path and electrically connecting them, the method further comprises:
providing protection structures at the connection positions between each of the branch paths and the main path, wrapping the connection positions between the branch paths and the main path by the protection structures, and connecting the protection structures with the connection positions between the branch paths and main path through an adhesive layer.

7. The method according to claim 1, wherein arranging each of the branch paths vertically with the main path and electrically connecting them comprise:
connecting the branch paths and main path electrically by welding, or;
connecting the branch paths to the main path through conductive connectors, where the branch paths are welded to the conductive connectors, and the conductive connectors are welded to the main path.
